(19) United States
(12) Patent Application Publication
(10) Pub. No.: US 2023/0401974 A1
(43) Pub. Date: Dec. 14, 2023

(54) METHOD SUITABLE FOR DRIVER TAKEOVER TRAINING OF MAN-MACHINE SHARED DRIVING VEHICLES

(71) Applicants: Hefei University of Technology, Hefei (CN); Intelligent Manufacturing Institute of HFUT, Hefei (CN)

(72) Inventors: Zhongxiang FENG, Hefei (CN); Ya GAO, Hefei (CN); Zeyang CHENG, Hefei (CN); Lei ZHANG, Hefei (CN); Zhipeng HUANG, Hefei (CN); Jiabin ZENG, Hefei (CN); Jingyu LI, Hefei (CN); Yubing ZHENG, Hefei (CN); Dianchen ZHU, Hefei (CN); Weihua ZHANG, Hefei (CN); Kang JIANG, Hefei (CN)

(73) Assignees: Hefei University of Technology, Hefei (CN); Intelligent Manufacturing Institute of HFUT, Hefei (CN)

(21) Appl. No.: 18/209,493

(22) Filed: Jun. 14, 2023

(30) Foreign Application Priority Data
Jun. 14, 2022 (CN) 202210669849.2

(51) Int. Cl. G09B 9/052; G09B 9/05

(52) U.S. Cl. CPC G09B 9/052; G09B 9/05

(57) ABSTRACT

A method suitable for driver takeover training of man-machine shared driving vehicle relates to the field of man-machine shared driving technology. The method includes: establishing database, situation-creation, establish a teaching model, take over training, evaluation and analysis of takeover ability. The method divides the driver's takeover behavior into a small operation action through the driver takeover training of the man-machine shared driving vehicle, defines where the driver's eyes need to observe when the takeover reminder appears, how the hands and feet need to be operated, and the sequence of these operations, solves the problems of the driver's tension and being in a flurry in the current sudden takeover reminder. In addition, through the evaluation and analysis of the takeover capability, the method can solve the problem that the existing technology cannot objectively evaluate the driver's takeover capability level.

### CROSS REFERENCE TO THE RELATED APPLICATIONS

This application is based upon and claims priority to Chinese Patent Application No. 202210669849.2, filed on Jun. 14, 2022, the entire contents of which are incorporated herein by reference.

### TECHNICAL FIELD

The present invention relates to the field of man-machine shared driving technology, and particularly relates to a method suitable for driver takeover training of man-machine shared driving vehicle.

### BACKGROUND

In the stage of man-machine shared driving, due to the immaturity of autonomous driving technology, the current autonomous driving system is not safe and reliable enough, and it is easy to cause traffic accidents in the natural traffic environment. When there are some problems during the driving process of man-machine shared driving vehicle.

In the process of vehicle autonomous driving, the higher the level of autonomous driving, the less attention the driver focuses on environmental monitoring and system operation, and the worse the ability to take over driving. The automatic system not only reduces the human operation load and improves the operation accuracy, but also brings new security risks in human factors, such as complacency, skill degradation, insufficient mental workload (when the automatic system is working), excessive mental workload (when suddenly required to take over driving), reduced situational awareness, etc. In the stage of autonomous man-machine shared driving, drivers often do not receive takeover training, they simply understand how to enter or exit the automation system by viewing the user manual, and do not know how to better respond to the takeover event. When facing with a sudden takeover reminder, the driver will appear some conditions such as tension be nervous, being in a flurry and so on, the failure to take over the vehicle in a timely manner within a limited time or the insufficient level of vehicle handling after the completion of the takeover is likely to lead to accidents. Therefore, it is particularly important to improve the takeover ability of autonomous vehicle drivers. So, how to improve the driver's takeover ability in the process of man-machine shared driving is an urgent problem to be solved.

In view of the above situations, designers need to design a set of reasonable methods for man-machine shared driving vehicle driver takeover training, to solve the current sudden takeover reminder, the driver's tension, being in a flurry, and the inability to objectively evaluate the driver's takeover ability level.

### SUMMARY

To remedy the shortcomings of the existing technical problems, the purpose of the present invention is to provide a method suitable for driver takeover training of man-machine shared driving vehicle. The present invention divides the driver's takeover behavior into a small operation action through the driver takeover training of the man-machine shared driving vehicle, defines where the driver's eyes need to observe when the takeover reminder appears, how the hands and feet need to be operated, and the sequence of these operations, solves the problems of the driver's tension and being in a flurry in the current sudden takeover reminder; in addition, through the evaluation and analysis of the takeover capability, the present invention can solve the problem that the existing technology cannot objectively evaluate the driver's takeover capability level.

The technical scheme of the invention is as follows.

A method suitable for man-machine shared driving vehicle driver takeover training, including the following steps:

(1) establishing database
forming the takeover scene library, and establishing the virtual simulation training scene model and virtual simulation equipment model;

(2) situation-Creation
according to the takeover scene library described in step (1), using the virtual simulation training scene model and the virtual simulation equipment model to simulate the takeover of the vehicle under different scenarios and different road events;

(3) establish a teaching model
according to the takeover situation of the vehicle simulated in step (2) under different scenarios and different road events, establishing the teaching model;

(4) takeover training
according to the takeover of the vehicle in different scenarios and different road events, carrying out the takeover training of the driver of the man-machine shared driving vehicle through the teaching model;

(5) evaluation and analysis of takeover ability
the teaching model described in step (3) is a guided teaching model.
the establishment of the guided teaching model, including the following steps:

(3.1) making training courseware according to training needs;

(3.2) selecting the training courseware, and establishing the virtual simulation training scene based on the training process of takeover behavior spectrum in the courseware content;

(3.3) simulating the vehicle state and takeover reminder mode when the virtual simulation takeover event occurs;

(3.4) conducting guided training through voice prompts in the virtual simulation training scene.

The man-machine shared driving vehicle driver takes over the training, including the following steps;

(4.1) entering the virtual simulation guided training mode;

(4.2) in the virtual simulation automatic driving environment, carrying out the preparation work before taking over;

(4.3) takeover request issued, take over; the specific takeover steps include:
a) observing the road environment and forming a preliminary understanding of the driving environment;
b) putting the right foot on the brake pedal, while the left hand on the steering wheel, preparing to control the vehicle in advance;
c) the driver moves his sight to the exit button, presses the button with his right hand and exits the automation system;
d) the driver moves the line of sight back to the front of the road, looks around, and observes the left and right rearview mirrors, at the same time, the right hand is placed on the steering wheel, according to the mastery and judgment of the driving environment, the subsequent vehicle handling is performed;

(4.4) the driver takeover training of man-machine shared driving vehicle is over.

The comprehensive evaluation method of takeover ability described in step (5) includes the following steps:

(5.1) collecting reference index data
collecting the index data of the takeover evaluation of the m-celebrity drivers of man-machine shared driving as the reference index data, including the driver's eye movement characteristics, physiological characteristics, vehicle handling and takeover behavior;
the eye movement characteristics include the percentage of fixation time and the average fixation time; the physiological characteristic indexes include RR interval and heart rate; the vehicle handling indicators include brake pedal force and lane shift amount; the takeover behavior index includes the first fixation road time;

(5.2) collecting training driver's index data
in the process of man-machine shared driving vehicle driver takeover training, the percentage of driver's fixation time, average fixation time, RR interval, heart rate, brake pedal force, lane shift amount, and the index data of the first fixation on the road are obtained as the index data to be evaluated;

(5.3) the standardization of data processing
standardized processing the above m+1 drivers Pᵢ's(i=1, 2 . . . m+1, m is a natural number) n evaluation indexes Xᵢⱼ (j=1, 2 . . . n, n is a natural number), converting to the range of [0-1], and obtaining standardized dimensionless quantity Xᵢⱼ′, the data standardization processing formula is as follows:

positive indexes:

$${X}_{ij}^{′} = \frac{Xij - min [ Xj ]}{max [ Xj ] - min [ Xj ]} \qquad ( 5.1 )$$

negative indexes:

$${X}_{ij}^{′} = \frac{max [ Xj ] - Xij}{max [ Xj ] - min [ Xj ]} \qquad ( 5.2 )$$

moderate indexes:

$${X}_{ij}^{′} = \{ \begin{matrix}\frac{Xij - min [ Xj ]}{X 0 - min [ Xj ]} , & Xij < X 0 \\ \frac{max [ Xj ] - Xij}{max [ Xj ] - X 0} , & Xij \geq X 0\end{matrix} \qquad ( 5.3 )$$

In formulas 5.1, 5.2, 5.3, Xᵢⱼ′ refers to the standardized dimensionless data, Xᵢⱼ refers to raw data, X₀ refers to the moderate value specified in the original data set.

(5.4) calculating the proportion of the value of the j-th index of the i-th person:

$${Y}_{ij} = \frac{{X}_{ij}}{{\sum }_{i = 1}^{m + 1} {X}_{ij}} \qquad ( 5.4 )$$

(5.5) calculating index information entropy:

eⱼ=−kΣᵢ₌₁^{m+1}(Yᵢⱼ×lnYᵢⱼ) (5.5)

(5.6) calculating information entropy redundancy:

dⱼ=1−eⱼ (5.6)

(5.7) calculating index weight

Wⱼ=dⱼ/Σ_{j=1dj}ⁿ (5.7)

(5.8) calculating the output of takeover capability evaluation
the normalized dimensionless data of the index data Xⱼ′ to be evaluated are input into Equation 5.8,

S=Σⁿⱼ₌₁Wⱼ*Xⱼ′ (5.8)
calculating the m+1 driver's takeover ability evaluation index value S, if the closer S is to 1, it indicates that the driver's ability to take over is stronger.

The advantages of the invention are:

The present invention provides a set of steps that enable a driver to take over control of an autonomous vehicle correctly and safely, the takeover behavior spectrum divides the driver's takeover behavior into small operational actions, and defines where the driver's eyes need to observe when the takeover reminder appears, how the hands and feet need to be operated, and the sequence of these operations, the content of the training is easy to understand and is very friendly to novices or unskilled people; the invention plays an important role in improving the driver's ability to take over in the process of man-machine shared driving.

2. The present invention uses the virtual simulation training scene model and the virtual simulation equipment model to simulate the vehicle takeover under different road events in different scenes; based on the training process of the takeover behavior spectrum in the courseware content, establishing a virtual simulation training scene, so that the trainers can be treated for immersive training, the training effect can be further improved, and the enthusiasm of the trainers can be promoted, besides, it can drive the enthusiasm of the training staff, make the simulation effect closer to the actual fault situation, and then improve the simulation effect of the fault.

3. The present invention adopts the comprehensive evaluation method to evaluate and analyze the takeover ability, and through the takeover training process of the driver of the man-machine shared driving vehicle, obtaining a number of index data of driver's eye movement characteristics, physiological characteristics, vehicle handling and takeover behavior, and calculating the evaluation index value of the driver's takeover ability directly, based on this, the takeover ability of the driver can be judged intuitively, and the driver can determine whether it is necessary to continue the takeover training of the driver of the man-machine shared driving vehicle according to the evaluation and analysis of the takeover ability.

### DETAILED DESCRIPTION OF THE EMBODIMENTS

To make the purpose, technical scheme and advantages of the present invention more clear, the following steps are described in detail in combination with the implementation examples. It should be understood that the specific implementation examples described here are used to explain the present invention and are not used to limit the present invention.

A method suitable for driver takeover training of man-machine shared driving vehicle,

(1) establishing database
forming the takeover scene library, and establishing the virtual simulation training scene model and virtual simulation equipment model;
the takeover scene takes a double-way six-lane highway as an example, with the speed limit of 120 km/h, double-way traffic flow applicable;
typical takeover events include: front road construction, system failure, obstacles in front, disappearance of front lane lines, etc., and the takeover time is 7 s in advance.

(2) situation-creation
according to the takeover scene library described in step (1), using the virtual simulation training scene model and the virtual simulation equipment model to simulate the takeover of the vehicle under different scenarios and different road events;

(3) establish a teaching model
according to the takeover situation of the vehicle simulated in step (2) under different scenarios and different road events, establishing the teaching model;

(4) takeover training
according to the takeover of the vehicle in different scenarios and different road events, carrying out the takeover training of the driver of the man-machine shared driving vehicle through the teaching model; training the trainers on the web or immersive VR equipment, when using the web side, through the PC device to operate the web side, realizing the simulation of virtual simulation training scene model, making the virtual simulation equipment model produce corresponding feedback; and the data acquisition device is used to collect a number of index data of eye movement characteristics, physiological characteristics, vehicle handling and takeover behavior during the training process.

(5) evaluation and analysis of takeover ability
the teaching model described in step (3) is a guided teaching model.
the establishment of the guided teaching model, including the following steps:

(3.1) making training courseware according to training needs;

(3.2) selecting the training courseware, and establishing the virtual simulation training scene based on the training process of takeover behavior spectrum in the courseware content;

(3.3) simulating the vehicle state and takeover reminder mode when the virtual simulation takeover event occurs;

(3.4) conducting guided training through voice prompts in the virtual simulation training scene.

Further, the man-machine shared driving vehicle takeover training, including the following steps:

(4.1) entering the virtual simulation guided training mode;

(4.2) in the virtual simulation automatic driving environment, carrying out the preparation work before taking over;

(4.3) takeover request issued, take over; the specific takeover steps include:
a) observing the road environment and forming a preliminary understanding of the driving environment;
b) putting the right foot on the brake pedal, while the left hand on the steering wheel, preparing to control the vehicle in advance;
c) the driver moves his sight to the exit button, presses the button with his right hand and exits the automation system;
d) the driver moves the line of sight back to the front of the road, looks around, and observes the left and right rearview mirrors, at the same time, the right hand is placed on the steering wheel, according to the mastery and judgment of the driving environment, the subsequent vehicle handling is performed;

(4.4) the driver takeover training of man-machine shared driving vehicle is over.

The comprehensive evaluation method of takeover ability described in step (5) includes the following steps:

(5.1) collecting reference index data
collecting the data indicators of the takeover evaluation of 14 man-machine shared driving vehicle drivers; percentage of fixation time, average fixation time, RR interval, heart rate, brake pedal force, lane shift amount, first fixation road time, as shown in Table 1, as a reference indicator data.

TABLE 1

| Percentage | Average | | HR | Brake | Lane | First |
|---|---|---|---|---|---|---|
| of fixation | fixation | RR | heart | pedal | shift | fixation |
| time | time | interval | rate | force | amount | road time |
| 0.12 | 0.40 | 0.86 | 67.43 | 0.00 | 0.05 | 0.90 |
| 0.18 | 0.25 | 0.71 | 85.08 | 0.17 | 0.04 | 0.65 |
| 0.16 | 0.69 | 0.78 | 75.38 | 0.07 | 0.05 | 0.26 |
| 0.10 | 0.33 | 0.73 | 87.01 | 0.00 | 0.04 | 0.69 |
| 0.20 | 0.30 | 0.95 | 63.27 | 0.03 | 0.10 | 0.75 |
| 0.16 | 0.35 | 0.77 | 78.20 | 0.20 | 0.07 | 0.42 |
| 0.30 | 0.35 | 0.71 | 86.61 | 0.02 | 0.10 | 0.74 |
| 0.18 | 0.32 | 0.85 | 71.08 | 0.04 | 0.05 | 0.68 |
| 0.93 | 0.27 | 0.74 | 84.17 | 0.01 | 0.05 | 1.39 |
| 0.43 | 0.55 | 0.82 | 73.17 | 0.17 | 0.07 | 1.23 |
| 0.20 | 0.47 | 0.86 | 68.31 | 0.07 | 0.08 | 1.07 |
| 0.23 | 0.42 | 0.78 | 79.08 | 0.01 | 0.09 | 0.42 |
| 0.05 | 0.23 | 0.77 | 80.51 | 0.22 | 0.06 | 0.69 |
| 0.22 | 0.12 | 0.99 | 61.28 | 0.10 | 0.07 | 1.02 |

(5.2) collecting training driver's index data
in the process of driver takeover training for the man-machine shared driving vehicles, obtaining the driver's index data including percentage of fixation time, average fixation time, RR interval, heart rate, brake pedal force, lane shift amount, and first fixation road time, as index data to be evaluated, as shown in Table 2

| Percentage | Average | | HR | Brake | Lane | First |
|---|---|---|---|---|---|---|
| of fixation | fixation | RR | heart | pedal | shift | fixation |
| time | time | interval | rate | force | amount | road time |
| 0.37 | 0.43 | 0.80 | 75.67 | 0.06 | 0.08 | 0.38 |

(5.3) the standardization of data processing
standardized processing the above 15 drivers Pᵢ's(i=1, 2, . . . 15) 7 evaluation indexes Xᵢⱼ (j=1, 2, . . . 7), converting to the range of [0-1], and obtaining standardized dimensionless quantity Xᵢⱼ′, as shown in Table 3, the data standardization processing formula is as follows:

positive indexes:

$${X}_{ij}^{′} = \frac{Xij - min [ Xj ]}{max [ Xj ] - min [ Xj ]} \qquad ( 5.1 )$$

negative indexes:

$${X}_{ij}^{′} = \frac{max [ Xj ] - Xij}{max [ Xj ] - min [ Xj ]} \qquad ( 5.2 )$$

moderate indexes:

$${X}_{ij}^{′} = \{ \begin{matrix}\frac{Xij - min [ Xj ]}{X 0 - min [ Xj ]} , & Xij < X 0 \\ \frac{max [ Xj ] - Xij}{max [ Xj ] - X 0} , & Xij \geq X 0\end{matrix} \qquad ( 5.3 )$$

In formulas 5.1, 5.2, 5.3, Xᵢⱼ′ refers to the standardized dimensionless data, Xᵢⱼ refers to raw data, X₀ refers to the moderate value specified in the original data set;

TABLE 3

| Percentage | Average | | HR | Brake | Lane | First |
|---|---|---|---|---|---|---|
| of fixation | fixation | RR | heart | pedal | shift | fixation |
| time | time | interval | rate | force | amount | road time |
| 0.07 | 0.49 | 0.53 | 0.76 | 1.00 | 0.88 | 0.43 |
| 0.15 | 0.23 | 0.00 | 0.07 | 0.23 | 1.00 | 0.66 |
| 0.13 | 1.00 | 0.25 | 0.45 | 0.69 | 0.92 | 1.00 |
| 0.06 | 0.37 | 0.07 | 0.00 | 1.00 | 0.96 | 0.62 |
| 0.18 | 0.31 | 0.86 | 0.92 | 0.85 | 0.00 | 0.57 |
| 0.13 | 0.40 | 0.20 | 0.34 | 0.11 | 0.50 | 0.86 |
| 0.29 | 0.41 | 0.00 | 0.02 | 0.89 | 0.00 | 0.58 |
| 0.15 | 0.35 | 0.51 | 0.62 | 0.84 | 0.80 | 0.63 |
| 1.00 | 0.26 | 0.11 | 0.11 | 0.94 | 0.92 | 0.00 |
| 0.43 | 0.75 | 0.40 | 0.54 | 0.24 | 0.52 | 0.14 |
| 0.17 | 0.61 | 0.54 | 0.73 | 0.69 | 0.36 | 0.29 |
| 0.20 | 0.52 | 0.25 | 0.31 | 0.94 | 0.16 | 0.86 |
| 0.00 | 0.20 | 0.21 | 0.25 | 0.00 | 0.60 | 0.62 |
| 0.20 | 0.00 | 1.00 | 1.00 | 0.55 | 0.49 | 0.33 |
| 0.36 | 0.54 | 0.32 | 0.44 | 0.72 | 0.41 | 0.90 |

(5.4) calculating the proportion of the value of the j-th index of the i-th person:

$${Y}_{ij} = \frac{{X}_{ij}}{{\sum }_{i = 1}^{m + 1} {X}_{ij}} \qquad ( 5.4 )$$

(5.5) calculating index information entropy:

eⱼ=−kΣᵢ₌₁^{m+1}(Yᵢⱼ×lnYᵢⱼ) (5.5)

(5.6) calculating information entropy redundancy:

dⱼ=1−eⱼ (5.6)

(5.7) calculating index weight

Wⱼ=dⱼ/Σ_{j=1dj}ⁿ (5.7)

Obtaining the information entropy value, information utility value and weight coefficient of each index, as shown in table 4 below.

| | Information | Information | weight |
|---|---|---|---|
| | entropy | utility | coefficient |
| Item | value e | value d | W |
| Percentage of fixation | 0.8757 | 0.1243 | 20.66% |
| time | | | |
| Average fixation time | 0.9432 | 0.0568 | 9.44% |
| RR interval | 0.8794 | 0.1206 | 20.03% |
| HR heart rate | 0.8960 | 0.1040 | 17.28% |
| Brake pedal force | 0.9375 | 0.0625 | 10.38% |
| Lane shift amount | 0.9203 | 0.0797 | 13.23% |
| First fixation road | 0.9459 | 0.0541 | 8.98% |
| time | | | |

(5.8) calculating the output of takeover capability evaluation

the normalized dimensionless data of the index data Xⱼ′ to be evaluated are input into Equation 5.8,

S=Σⁿⱼ₌₁Wⱼ*Xⱼ′ (5.8)

S=0.36*20.66%+0.54*9.44%+0.32*20.03%+0.44*17.28%+0.72*10.38%+0.41*13.23%+0.90*8.98%=0.48
calculating the driver's takeover ability evaluation index value S, if the closer S is to 1, it indicates that the driver's ability to take over is stronger.

The present invention is inspired by the behavior spectrum theory, the driver of the man-machine shared driving vehicle also has its specific ‘behavior spectrum’ when taking over, that is, a set of steps that enable the driver to take over the control of the autonomous vehicle correctly and safely. The takeover behavior spectrum divides the driver's takeover behavior into small operational actions, and defines where the driver's eyes need to observe when the takeover reminder appears, how the hands and feet need to be operated, and the sequence of these operations. Based on this, this application provides a method suitable for driver takeover training of man-machine shared driving vehicle, in the present invention, through the establishment of database and situation generation, the simulation vehicle takeover under different road events in different scenarios, in the virtual simulation training scene, the driver carries out the human-machine co-driving vehicle driver takeover training according to the teaching model, and realizes the evaluation and analysis of takeover capability according to the index data collected during the training process.

Although the embodiments of the invention have been shown and described, it is understandable to ordinary technicians in the field that these embodiments can be varied, modified, replaced and modified without departing from the principle and spirit of the invention, and the scope of the invention is limited by the accompanying claims and their equivalents.

What is claimed is:

1. A method suitable for driver takeover training of a man-machine shared driving vehicle, comprising the following steps:
(1) establishing database
forming a takeover scene library, and establishing a virtual simulation training scene model and a virtual simulation equipment model;
(2) situation-creation
according to the takeover scene library described in step (1), using the virtual simulation training scene model and the virtual simulation equipment model to simulate a takeover situation of the man-machine shared driving vehicle under different scenarios and different road events;
(3) establish a teaching model
according to the takeover situation of the man-machine shared driving vehicle simulated in step (2) under different scenarios and different road events, establishing the teaching model;
(4) takeover training
according to the takeover situation of the man-machine shared driving vehicle in different scenarios and different road events, carrying out the takeover training of a driver of the man-machine shared driving vehicle through the teaching model, and
(5) evaluation and analysis of takeover ability.

2. The method suitable for driver takeover training of the man-machine shared driving vehicle according to claim 1, wherein the teaching model described in step (3) is a guided teaching model.

3. The method suitable for driver takeover training of the man-machine shared driving vehicle according to claim 2, wherein the establishment of the guided teaching model comprises the following steps:
(3.1) making training courseware according to training needs;
(3.2) selecting the training courseware, and establishing the virtual simulation training scene based on a training process of takeover behavior spectrum in a courseware content;
(3.3) simulating a vehicle state and a takeover reminder mode when a virtual simulation takeover event occurs; and
(3.4) conducting guided training through voice prompts in the virtual simulation training scene.

4. The method suitable for driver takeover training of the man-machine shared driving vehicle according to claim 3, wherein the man-machine shared driving vehicle driver takes over the training, comprising the following steps:
(4.1) entering a virtual simulation guided training mode;
(4.2) in a virtual simulation automatic driving environment, carrying out a preparation work before taking over;
(4.3) takeover request issued, take over; the specific takeover steps comprise:
a) observing a road environment and forming a preliminary understanding of the virtual simulation automatic driving environment;
b) putting a right foot on a brake pedal, while a left hand on a steering wheel, preparing to control the man-machine shared driving vehicle in advance;
c) the driver moves a line of his sight to an exit button, presses the exit button with his right hand and exits an automation system; and
d) the driver moves the line of sight back to a front of a road, looks around, and observes left and right rearview mirrors, at the same time, the right hand is placed on the steering wheel, according to a mastery and judgment of the virtual simulation automatic driving environment, the subsequent vehicle handling is performed; and
(4.4) the driver takeover training of the man-machine shared driving vehicle is over.

5. The method suitable for driver takeover training of the man-machine shared driving vehicle according to claim 1, wherein a comprehensive evaluation method of takeover ability described in step (5) comprises the following steps:
(5.1) collecting reference index data
collecting index data of the takeover evaluation of m-celebrity drivers of man-machine shared driving as reference index data, comprising the driver's eye movement characteristics, physiological characteristics, vehicle handling indicators and takeover behavior index;
the eye movement characteristics comprise a percentage of fixation time and an average fixation time; the physiological characteristic indexes comprise RR interval and heart rate; the vehicle handling indicators comprise brake pedal force and lane shift amount; the takeover behavior index comprises a first fixation road time;
(5.2) collecting training driver's index data
in a process of man-machine shared driving vehicle driver takeover training, the percentage of driver's fixation time, the average fixation time, the RR interval, the heart rate, the brake pedal force, the lane shift amount, and the index data of the first fixation on the road are obtained as the index data to be evaluated;
(5.3) standardization of data processing
standardized processing the above m+1 drivers Pᵢ's (i=1, 2 . . . m+1, m is a natural number) n evaluation indexes Xᵢⱼ (j=1, 2, . . . n, n is a natural number), converting to a range of [0, 1], and obtaining standardized dimensionless quantity Xᵢⱼ′, the data standardization processing formula is as follows:
positive indexes:
$${X}_{ij}^{′} = \frac{Xij - min [ Xj ]}{max [ Xj ] - min [ Xj ]} \qquad ( 5.1 )$$
negative indexes:
$${X}_{ij}^{′} = \frac{max [ Xj ] - Xij}{max [ Xj ] - min [ Xj ]} \qquad ( 5.2 )$$
moderate indexes:
$${X}_{ij}^{′} = \{ \begin{matrix}\frac{Xij - min [ Xj ]}{X 0 - min [ Xj ]} , & Xij < X 0 \\ \frac{max [ Xj ] - Xij}{max [ Xj ] - X 0} , & Xij \geq X 0\end{matrix} \qquad ( 5.3 )$$
in formulas 5.1, 5.2, 5.3, Xᵢⱼ′ refers to standardized dimensionless data, Xᵢⱼ refers to raw data, X₀ refers to a moderate value specified in an original data set.
(5.4) calculating a proportion of a value of a j-th index of an i-th person:
$${Y}_{ij} = \frac{{X}_{ij}}{{\sum }_{i = 1}^{m + 1} {X}_{ij}} \qquad ( 5.4 )$$
(5.5) calculating index information entropy:
eⱼ=−kΣᵢ₌₁^{m+1}(Yᵢⱼ+lnYᵢⱼ) (5.5)
(5.6) calculating information entropy redundancy:
dⱼ=1−eⱼ (5.6)
(5.7) calculating index weight
Wⱼ=dⱼ/Σ_{j=1dj}ⁿ (5.7)
(5.8) calculating an output of takeover capability evaluation
normalized dimensionless data of the index data Xⱼ′ to be evaluated are input into Equation 5.8,
S=Σⱼ₋₁ⁿWⱼ*Xⱼ′ (5.8)
calculating the m+1 driver's takeover ability evaluation index value S, if the closer S is to 1, it indicates that the driver's ability to take over is stronger.
